(19) United States
(12) Patent Application Publication
(10) Pub. No.: US 2025/0261371 A1
(43) Pub. Date: Aug. 14, 2025

(54) VERTICAL STRUCTURE MEMORY DEVICE

(71) Applicant: Samsung Electronics Co., Ltd., Suwon-si (KR)

(72) Inventors: Sunho KIM, Suwon-si (KR); Kyunghun KIM, Suwon-si (KR); Hyungyung KIM, Suwon-si (KR); Minhyun LEE, Suwon-si (KR); Seokhoon CHOI, Suwon-si (KR); Hoseok HEO, Suwon-si (KR)

(73) Assignee: Samsung Electronics Co., Ltd., Suwon-si (KR)

(21) Appl. No.: 19/024,644

(22) Filed: Jan. 16, 2025

(30) Foreign Application Priority Data
Feb. 13, 2024 (KR) 10-2024-0020665

(51) Int. Cl. H10B 43/27; H10B 43/10; H10D 30/69

(52) U.S. Cl. CPC H10B 43/27; H10B 43/10; H10D 30/693; H10D 30/697

(57) ABSTRACT

A vertical structure memory device includes a cell string. The cell string includes a channel layer extending in a direction perpendicular to a substrate, a charge trap layer on the channel layer and including a nitride doped with scandium (Sc), and a plurality of gate electrodes on the charge trap layer. A content of doped Sc in the charge trap layer is 2 atomic percent (at %) to 10 at % as a proportion of a total composition of the charge trap layer.

### CROSS-REFERENCE TO RELATED APPLICATION

This application is based on and claims priority under 35 U.S.C. § 119 to Korean Patent Application No. 10-2024-0020665, filed on Feb. 13, 2024, in the Korean Intellectual Property Office, the disclosure of which is incorporated by reference herein in its entirety.

### BACKGROUND

### 1. Field

The inventive concepts relate to vertical structure memory devices.

### 2. Description of the Related Art

A non-volatile memory includes a plurality of memory cells each retaining information even when supply of electrical power is blocked and being capable of using stored information whenever electrical power is supplied again. A non-volatile memory device may be widely applied to mobile phones, digital cameras, mobile computer devices, etc.

Recently, as high integration and low power are required, vertical NAND (V-NAND) flash memory devices have been developed, and as the degree of integration increases, interest in improving charge retention properties of a memory cell by reducing charge transfer between adjacent memory cells has been increasing.

### SUMMARY

Some example embodiments provide a vertical structure memory device including a nitride doped with rare-earth elements.

Some example embodiments provide a vertical structure memory device including a charge trap layer having a high charge retention property.

Some example embodiments will be set forth in part in the description which follows and, in part, will be apparent from the description, or may be learned by practice of the example embodiments of the inventive concepts.

According to some example embodiments, a vertical structure memory device may include a cell string. The cell string may include a channel layer extending in a direction perpendicular to a substrate, a charge trap layer on the channel layer, the charge trap layer including a nitride doped with scandium (Sc), and a plurality of gate electrodes on the charge trap layer. A content of doped Sc in the charge trap layer may be 2 atomic percent (at %) to 10 at % as a proportion of a total composition of the charge trap layer. The nitride may include at least one of silicon nitride or silicon oxynitride.

The nitride may include aluminum oxynitride.

The content of doped Sc in the charge trap layer may be 2.7 at % to 5 at %.

A surface density of the doped Sc in the charge trap layer may be equal to or greater than 10¹⁴ atoms/cm².

The charge trap layer may include an amorphous matrix, the amorphous matrix including the nitride, and nano-crystals distributed in the amorphous matrix, the nano-crystals having semiconductor characteristics.

The nano-crystals may include the doped Sc thereon.

The nano-crystals may include the nitride grown based on using the doped Sc as a crystal nucleus.

The nitride may include at least one of silicon nitride or silicon oxynitride.

The nitride may include aluminum oxynitride.

The vertical structure memory device may further include a first insulating layer between each separate gate electrode of the plurality of gate electrodes and the charge trap layer, the first insulating layer including aluminum oxide. The vertical structure memory device may further include a second insulating layer between the charge trap layer and the first insulating layer, the second insulating layer including silicon oxide.

The first insulating layer, the second insulating layer, and the charge trap layer may be sequentially arranged such that the second insulating layer is between the first insulating layer and the charge trap layer.

The vertical structure memory device may further include a tunneling layer between the channel layer and the charge trap layer. One surface of the charge trap layer may be in contact with the tunneling layer and an opposite surface of the charge trap layer may be in contact with the second insulating layer.

The charge trap layer may include a first diffusion barrier layer on one surface of the nitride.

The charge trap layer may include a second diffusion barrier layer on another surface of the nitride, the other surface of the nitride being opposite to the one surface of the nitride.

The first diffusion barrier layer and the second diffusion barrier layer may each independently include silicon nitride or silicon oxynitride.

The charge trap layer may have a cylindrical shape surrounding the channel layer.

The plurality of gate electrodes may be spaced apart from each other in the direction perpendicular to the substrate.

Each gate electrode of the plurality of gate electrodes may surround the charge trap layer.

An electronic apparatus may include the vertical structure memory device.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a perspective view of a vertical structure memory device according to some example embodiments;

FIG. 2 is a cross-sectional view of a cell string of FIG. 1 according to some example embodiments;

FIG. 3 is an enlarged view of part A in the memory cell of FIG. 2 according to some example embodiments;

FIG. 4 is a diagram schematically showing an electronic band structure taken along line I-I′ of FIG. 3 according to some example embodiments;

FIG. 5 is a graph of a first experimental example showing trap density and dielectric constant according to the content of scandium doped on a charge trap layer according to some example embodiments;

FIG. 6 is a graph of a second experimental example showing trap depth according to the content of scandium doped on a charge trap layer according to some example embodiments;

FIG. 7 is a graph showing an energy band according to the content of scandium doped on a charge trap layer according to some example embodiments;

FIG. 8 is a cross-sectional view of a cell string according to some example embodiments;

FIG. 9 is an enlarged view of part B in the memory cell of FIG. 8 according to some example embodiments;

FIG. 10 is a diagram schematically showing an electronic band structure taken along line II-II′ of FIG. 9 according to some example embodiments;

FIG. 11 is a diagram schematically showing an electronic band structure taken along line III-III′ of FIG. 9 according to some example embodiments;

FIG. 12 is a cross-sectional view of a cell string according to some example embodiments;

FIG. 13 is an enlarged view of part C in the memory cell of FIG. 12 according to some example embodiments;

FIG. 14 is a cross-sectional view of a cell string according to some example embodiments;

FIG. 15 is an enlarged view of part D in the memory cell of FIG. 14 according to some example embodiments;

FIG. 16 is a diagram schematically showing an electronic band structure taken along line IV-IV′ of FIG. 15 according to some example embodiments; and

FIG. 17 is a schematic view of an electronic apparatus according to some example embodiments.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, some example embodiments will be described in detail with reference to accompanying drawings. In the drawings, like reference numerals denote like components, and sizes of components in the drawings may be exaggerated for convenience of explanation. Some example embodiments of the inventive concepts are capable of various modifications and may be embodied in many different forms. When a layer, a film, a region, or a panel is referred to as being “on” another element, it may be directly on/under/at left/right sides of the other layer or substrate, or intervening layers may also be present. An expression used in the singular encompasses the expression of the plural, unless it has a clearly different meaning in the context. It will be further understood that when a portion is referred to as “comprising” another component, the portion may not exclude another component but may further comprise another component unless the context states otherwise. The use of the term of “the above-described” and similar indicative terms may correspond to both the singular forms and the plural forms. Also, the steps of all methods described herein may be performed in any suitable order unless otherwise indicated herein or otherwise clearly contradicted by context. Also, the terms “ . . . unit”, “ . . . module” used herein specify a unit for processing at least one function or operation, and this may be implemented with hardware or software or a combination of hardware and software. Furthermore, the connecting lines or connectors shown in the drawings are intended to represent example functional relationships and/or physical or logical couplings between the various elements. It should be noted that many alternative or additional functional relationships, physical connections, or logical connections may be present in a practical device. The use of any and all examples, or example language provided herein, is intended merely to better illuminate the inventive concepts and does not pose a limitation on the scope of the present inventive concepts unless otherwise claimed.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%). It will be understood that elements and/or properties thereof may be recited herein as being “the same” or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof. When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

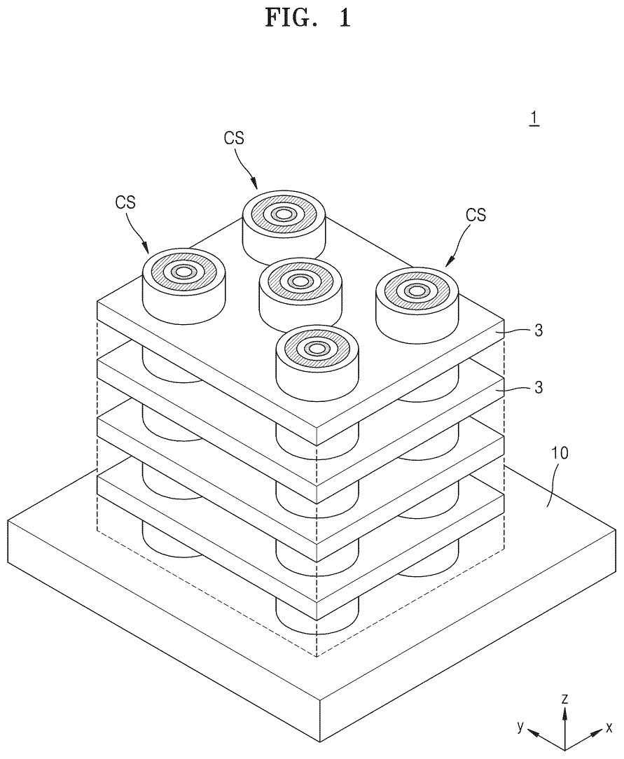

FIG. 1 is a perspective view of a vertical structure memory device 1 according to some example embodiments.

Referring to FIG. 1, the vertical structure memory device 1 according to some example embodiments may include a plurality of cell strings CS disposed on (e.g., directly or indirectly on) a substrate 10. Here, each of the cell strings CS may extend in a direction perpendicular to the substrate 10 (z-axis direction in FIG. 1). The plurality of cell strings CS may be disposed in various types on the substrate 10. It will be understood that a direction perpendicular to the substrate 10 may be a direction perpendicular to an in-plane direction of the substrate 10, a direction perpendicular to an upper surface and/or a bottom surface of the substrate 10, any combination thereof, or the like.

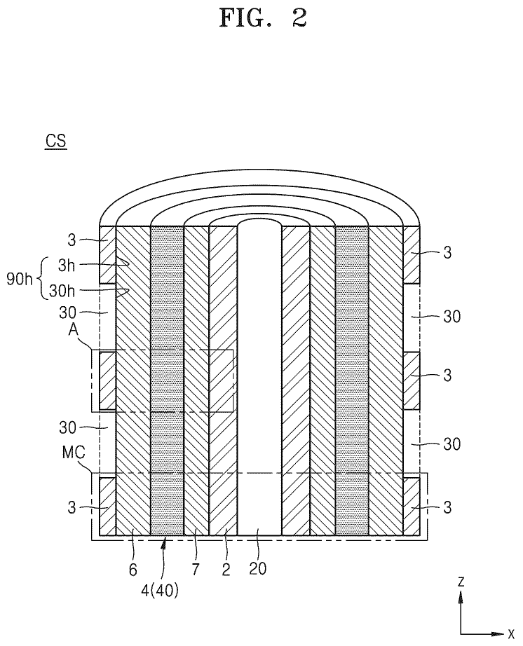

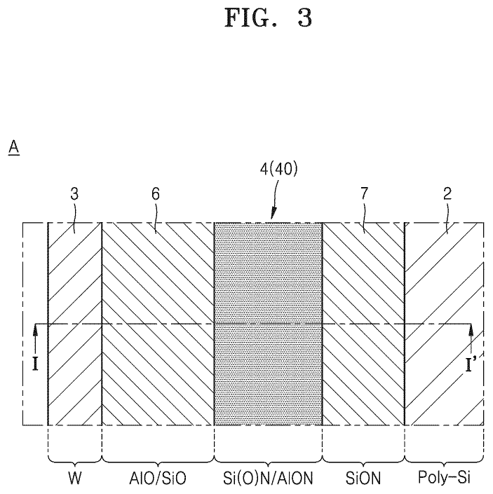

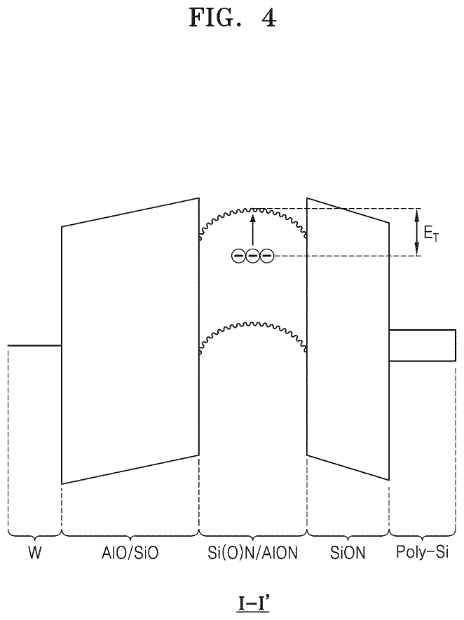

FIG. 2 is a cross-sectional view of a cell string CS of FIG. 1 according to some example embodiments. FIG. 3 is an enlarged view of part A in a memory cell MC of FIG. 2 according to some example embodiments. FIG. 4 is a diagram schematically showing an electronic band structure taken along line I-I′ of FIG. 3 according to some example embodiments.

Referring to FIG. 1 to FIG. 4, each cell string CS according to some example embodiments may include a plurality of memory cells MC stacked in a direction perpendicular to the substrate 10. The cell string CS may include a plurality of gate electrodes 3 that are stacked to be spaced apart from one another (e.g., spaced apart from each other) in the direction perpendicular to the substrate 10 (e.g., z-axis direction). Each cell string CS may include an insulating layer 6, a charge trap layer 4, a tunneling layer 7, and a channel layer 2 that are sequentially provided in each separate gate electrode 3 in an arrangement direction that is in parallel to the substrate 10 (e.g., an x-axis direction as shown in FIG. 2). It will be understood that a direction parallel to the substrate 10 may be a direction parallel to an in-plane direction of the substrate 10, a direction parallel to an upper surface and/or a bottom surface of the substrate 10, any combination thereof, or the like. Here, the insulating layer 6, the charge trap layer 4, the tunneling layer 7, and the channel layer 2 may be each provided to extend in a direction perpendicular to the substrate 10 (e.g., z-axis direction) and may be shared by the plurality of memory cells MC (e.g., the plurality of memory cells MC of a given cell string CS).

Each of the memory cells MC may be configured by one or more gate electrodes 3, and the insulating layer 6, the charge trap layer 4, the tunneling layer 7, and the channel layer 2 provided at one or more locations corresponding to the one or more gate electrodes 3. A source and a drain may be provided in the channel layers 2 located under and on each memory cell MC, and a channel corresponding to each gate electrode 3 of each memory cell MC may be formed in the channel layer 2 between the source and drain. In each memory cell MC, when a certain voltage is applied to the gate electrode 3 of the memory cell MC, charges flowing between the source and the drain of the channel layer 2 corresponding to the gate electrode 3 pass through the tunneling layer 7 and are trapped by the charge trap layer 4, thereby storing information. As shown in FIG. 4, the charges trapped by the charge trap layer 4 may have a certain trap depth ET.

The substrate 10 according to some example embodiments may include various materials. For example, the substrate 10 may include a single-crystalline silicon substrate 10, a compound semiconductor substrate 10, a silicon on insulator (SOI) substrate 10, etc., but is not limited thereto. Also, the substrate 10 may further include, for example, an impurity area obtained through a doping process, an electronic device such as a transistor, or a periphery circuit for selecting and controlling the memory cells MC storing data.

On the substrate 10 according to some example embodiments, spacers 30 and the gate electrodes 3 may be alternately arranged (e.g., alternately stacked) in the direction perpendicular to the substrate 10 (e.g., z-axis direction). There may be a plurality of gate electrodes 3 and a plurality of spacers 30 alternately stacked on the substrate 10 in a given vertical structure memory device 1. Each of the plurality of gate electrodes 3 may be provided to surround the charge trap layer 4. Each spacer 30 and each gate electrode 3 may be provided in parallel to the substrate 10 (e.g., each spacer 30 and each gate electrode 3 may have a respective in-plane direction that extends in parallel to an in-plane direction of the substrate 10). The spacers 30 may be arranged between the gate electrodes 3 (e.g., one or more spacers 30 may each be between separate, respective pairs of adjacent gate electrodes 3 in the direction perpendicular to the substrate 10) so that the gate electrodes 3 may be spaced apart a certain distance from each other in the direction perpendicular to the substrate 10. The spacer 30 may have a mold structure that is alternately stacked with the gate electrode 3 on the substrate 10 so that the gate electrodes 3 are spaced apart from each other. The spacer 30 may insulate the gate electrodes 3 from each other so that the gate electrodes 3 may not be electrically connected to each other. However, functions and performances of the spacers 30 are not limited to the above description.

The gate electrode 3 according to some example embodiments may control the corresponding channel layer 2. A word line may be electrically connected to the gate electrode 3. The gate electrode 3 may include the word line. The gate electrode 3 may include, for example, a metal material having excellent electric conductivity such as gold (Au), metal nitride, silicon doped with impurities, or a two-dimensional conductive material. However, the material of the gate electrode 3 is not limited to the above examples.

Channel holes 3h, 30h may be formed in the gate electrode 3 and the spacer 30 so as to pass through the gate electrode 3 and the spacer 30 in the direction perpendicular to the substrate 10. One or more of the channel holes 3h, 30h may be formed to have, for example, a circular cross-section. The channel holes 3h, 30h which at least partially overlap in the direction perpendicular to the substrate 10 (e.g., the z-axis direction) may collectively define a channel hole 90h corresponding to a given cell string CS and extending through the plurality of gate electrodes 3 and the plurality of spacers 30 stacked on the substrate 10 in the direction perpendicular to the substrate 10.

The insulating layer 6, the charge trap layer 4, the tunneling layer 7, and the channel layer 2 may be sequentially provided on the internal wall of the channel hole 90h. Here, each of the insulating layer 6, the charge trap layer 4, the tunneling layer 7, and the channel layer 2 may be formed to have a cylindrical shape extending in the direction perpendicular to the substrate 10. A filling insulating layer 20 may be provided in the channel layer 2 to fill in the channel holes, for example such that the filling insulating layer 20 has a cylindrical shape extending in the direction perpendicular to the substrate 10, and each of the insulating layer 6, the charge trap layer 4, the tunneling layer 7, and the channel layer 2 may be formed to have a cylindrical shape surrounding the filing insulting layer in a plane extending parallel to the substrate 10 and extend paraxial and/or coaxial to the filling insulating layer 20. The filling insulating layer 20 may include, for example, silicon oxide or air (e.g., a gas comprising one or more of nitrogen, oxygen, carbon dioxide, argon, or the like), but is not limited thereto.

The channel layer 2 may include a semiconductor material. The channel layer 2 may include, for example, Si, Ge, SiGe, group III-V semiconductor, etc. Also, the channel layer 2 may include, for example, oxide semiconductor, nitride 40, oxynitride semiconductor, two-dimensional (2D) semiconductor material, quantum dots, or organic semiconductor.

In some example embodiments, the oxide semiconductor may include, for example, InGaZnO, etc., the 2D semiconductor material may include, for example, transition metal dichalcogenide (TMD) or graphene, and the quantum dot may include colloidal quantum dot (QD), a nano-crystal structure, etc. However, some example embodiments are not limited to the above examples.

The channel layer 2 may further include a dopant. In some example embodiments, the dopant may include a p-type dopant or an n-type dopant. The p-type dopant may include, for example, a group III element such as B, Al, Ga, In, etc., and the n-type dopant may include, for example, a group V element such as P, As, Sb, etc.

The insulating layer 6, the charge trap layer 4, and the tunneling layer 7 may be provided between the gate electrode 3 and the channel layer 2. The insulating layer 6 may be provided on the internal wall of the channel hole 90h to come into contact with each of the spacer 30 and the gate electrode 3. The insulating layer 6 may include, for example, silicon oxide or metal oxide, but is not limited thereto. The tunneling layer 7 is a layer in which tunneling of charges occurs and may include, for example, silicon oxide, silicon nitride, silicon oxynitride, or metal oxide, but is not limited thereto. The tunneling layer 7 may be disposed between (e.g., directly or indirectly between) the channel layer 2 and the charge trap layer 4, but is not limited thereto.

The charge trap layer 4 according to some example embodiments may include the nitride 40. The nitride 40 may be and/or include a nitride compound. The charge trap layer 4 may include, for example, silicon nitride. The charge trap layer 4 may include, for example, silicon oxynitride. The charge trap layer 4 may include both the silicon nitride and silicon oxynitride, or may selectively include the silicon nitride or silicon oxynitride. However, the material in the charge trap layer 4 is not limited to the above description. For example, the charge trap layer 4 may include aluminum oxynitride.

In addition, the charge trap layer 4 may further include a dopant (e.g., in addition to including the nitride 40), such that the nitride 40 included in the charge trap layer 4 may be doped with the dopant and thus the charge trap layer 4 may be understood to include the nitride 40 doped with the dopant. Here, the dopant may include a rare-earth element. The dopant may include, for example, scandium (Sc) and may be referred to herein as doped Sc. The dopant may include, for example, lanthanide element such as Ce, Pr, Nd, Pm, Sm, Gd, Tb, Dy, Ho, Er, Tm, Yb, Lu, etc. When the rare-earth element is doped on the charge trap layer 4, the trap depth ET of the charge trap layer 4 may be increased. When the rare-earth element is doped on the charge trap layer 4, a dielectric constant k of the charge trap layer 4 may increase. When the rare-earth element is doped on the charge trap layer, trap density NT of the charge trap layer 4 may increase. The rare-earth element doped on the charge trap layer 4 may act as an oxygen scavenger on the charge trap layer 4, but is not limited thereto.

When the dielectric constant of the charge trap layer 4 increases, the memory MC may have an excellent (e.g., increased, improved, etc.) read window and thus may have improved data storage capability. When the dielectric constant of the charge trap layer 4 increases, the memory MC may have an excellent (e.g., increased, improved, etc.) charge retention property and thus may have improved data storage capability. When the trap density NT of the charge trap layer 4 increases, the memory cell MC may have excellent (e.g., increased, improved, etc.) charge retention property and thus may have improved data storage capability. When the trap density of the charge trap layer 4 increases, the memory MC may have excellent (e.g., increased, improved, etc.) read window and thus may have improved data storage capability. As a result, a vertical structure memory device, and any device including same (e.g., a memory device, electronic apparatus, or the like) may have improved data storage capabilities, including improved charge retention, stored data retention, improved read window, or the like, and thus may have improved data storage functionality and improved data storage reliability, based on the vertical structure memory device including a charge trap layer that includes a nitride doped with a dopant (e.g., scandium), for example wherein the content of the dopant (e.g., doped Sc) in the charge trap layer is 2 atomic percent (at %) to 10 at %.

Hereinafter, charge trap layers 4 doped with Sc according to some example embodiments are described below.

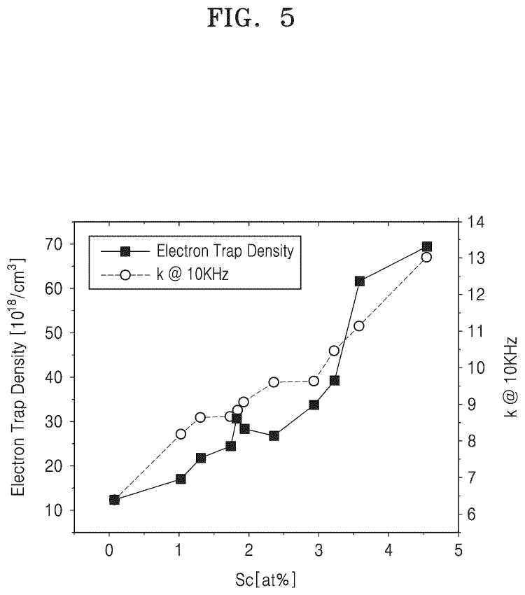

FIG. 5 is a graph of a first experimental example showing trap density and dielectric constant according to the content of Sc doped on the charge trap layer 4 according to some example embodiments.

The first experimental example of FIG. 5 is an example in which the trap density and dielectric constant are measured while doping the charge trap layer 4 including silicon nitride with Sc, where such charge trap layer 4 may be the charge trap layer 4 of the vertical structure memory device 1 shown in FIG. 1-4, although example embodiments are not limited thereto.

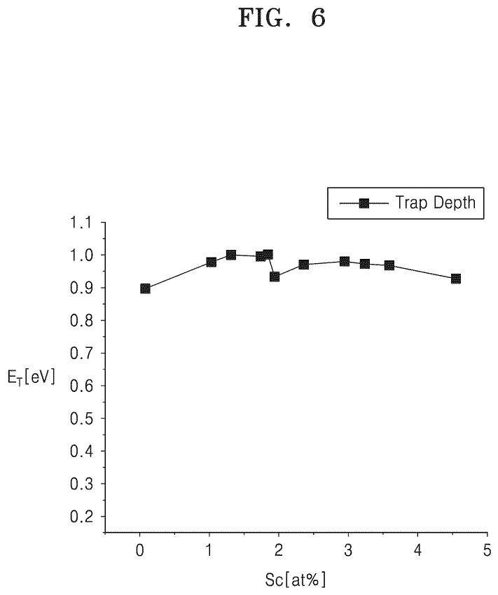

FIG. 6 is a graph of a second experimental example showing trap depth according to the content of Sc doped on the charge trap layer 4 according to some example embodiments.

The second experimental example of FIG. 6 is an example in which the electron trap density and dielectric constant are measured while doping the charge trap layer 4 including silicon nitride with Sc, where such charge trap layer 4 may be the charge trap layer 4 of the vertical structure memory device 1 shown in FIG. 1-4, although example embodiments are not limited thereto.

Referring to FIGS. 5 and 6, when the charge trap layer 4 is doped with Sc, such that a content of doped Sc in the charge trap layer 4 increases, the electron trap density of the charge trap layer 4 increases. Accordingly, an electron trap density of the charge trap layer 4 may be proportional to a content of doped Sc in the charge trap layer 4. Also, when the charge trap layer 4 is doped with Sc, the dielectric constant k of the charge trap layer 4 increases. Accordingly, a dielectric constant k of the charge trap layer 4 may be proportional to a content of doped Sc in the charge trap layer 4.

In addition, still referring to FIGS. 5 and 6, when the charge trap layer 4 is doped with Sc, the trap depth of the charge trap layer 4 may increase by a relatively small amount. When the charge trap layer 4 is doped with Sc, an increase in the trap depth of the charge trap layer 4 (e.g., a proportional increase, for example a percentage increase) may not be greater than an increase (e.g., a proportional increase, for example a percentage increase) in the electron trap density. When the charge trap layer 4 is doped with Sc, the increase in the trap depth of the charge trap layer 4 (e.g., a proportional increase, for example a percentage increase) may not be greater than the increase (e.g., a proportional increase, for example a percentage increase) in the dielectric constant. When the charge trap layer 4 is doped with Sc, the increase in the dielectric constant of the charge trap layer 4 (e.g., a proportional increase, for example a percentage increase) may be greater than the increase (e.g., a proportional increase, for example a percentage increase) in the trap depth. When the charge trap layer 4 is doped with Sc, the increase in the electron trap density of the charge trap layer 4 (e.g., a proportional increase, for example a percentage increase) may be greater than the increase (e.g., a proportional increase, for example a percentage increase) in the trap depth. However, the above description about the increase in the trap depth of the charge trap layer 4 is an example, and some example embodiments are not limited thereto.

Here, even when the increase in the trap depth of the charge trap layer 4 doped with Sc is not large (e.g., is less than 10 atomic percent (at %) at a proportion or ratio of Sc to the total composition of the charge trap layer 4, as a ratio of Sc doped on the charge trap layer 4 increases, the charge retention property may increase, such that the charge retention property may be proportional to the content (e.g., at %) of the doped SC in the charge trap layer 4. The increase in the charge retention property as the ratio of Sc doped on the charge trap layer 4 increases may be because of being affected by the increase in the dielectric constant of the charge trap layer 4. The increase in the charge retention property as the ratio of Sc doped on the charge trap layer 4 increases may be because of being affected by the increase in the electron trap density of the charge trap layer 4. However, the charge retention property of the charge trap layer 4 doped with Sc is not limited to the above description.

In addition, when the silicon nitride is doped with Sc, it may be identified that the trap depth of the charge trap layer 4 has local minimum (e.g., a minimum within a 10% range of doped Sc content in the charge trap layer, a minimum within a 20% range of doped Sc content in the charge trap layer, a minimum within a 30% range of doped Sc content in the charge trap layer, a minimum within a 40% range of doped Sc content in the charge trap layer, etc.) when the content of Sc in the charge trap layer 4 is about 2 at % (atomic percent) (e.g., as a proportion of a total composition of the charge trap layer 4). Also, when the content of Sc in the charge trap layer 4 is about 2 at %, it may be identified that the electron trap density of the charge trap layer 4 has local maximum (e.g., a maximum within a 10% range of doped Sc content in the charge trap layer, a maximum within a 20% range of doped Sc content in the charge trap layer 4, a maximum within a 0.5 at % range of doped Sc content values in the charge trap layer 4, etc.). Here, when comparing with the silicon nitride that is not doped with Sc, the charge trap layer 4 has excellent trap depth and trap density even when the content of Sc doped on the silicon nitride is about 2 at %. As such, it is identified that the charge trap layer 4 has excellent charge retention property when the content of Sc doped on the silicon nitride in the charge trap layer 4 is about 2 at % or greater. As a result, a vertical structure memory device, and any device including same (e.g., a memory device, electronic apparatus, or the like) may have improved data storage capabilities, including improved charge retention, stored data retention, improved read window, or the like, and thus may have improved data storage functionality and improved data storage reliability, based on the vertical structure memory device including a charge trap layer that includes a nitride doped with scandium wherein the content of the dopant (e.g., doped Sc) in the charge trap layer is equal to or greater than about 2 atomic percent (at %).

Also, it is identified that the electron trap density and the dielectric constant of the charge trap layer 4 stably increase (e.g., increase at a linear or substantially linear rate as the content of doped Sc in the charge trap layer 4 increases), when the content of Sc is about 2.7 at % or greater. Also, it is identified that the charge trap layer 4 having high processing reliability may be manufactured when the content of Sc is about 2.7 at % or greater. As a result, a vertical structure memory device, and any device including same (e.g., a memory device, electronic apparatus, or the like) may have improved data storage capabilities, including improved charge retention, stored data retention, improved read window, or the like, and thus may have improved data storage functionality and improved data storage reliability, based on the vertical structure memory device including a charge trap layer that includes a nitride doped with scandium wherein the content of the dopant (e.g., doped Sc) in the charge trap layer is equal to or greater than about 2.7 atomic percent (at %).

However, the above description about the content of Sc is an example, and example embodiments are not limited to the above examples. The content of Sc doped on the silicon nitride may be variously expressed. For example, the content of Sc doped on the silicon nitride may be expressed as a surface density of Sc on the charge trap layer 4 (e.g., on an outer surface of the charge trap layer 4 which many be facing and/or contacting the channel layer 7 or the gate electrode 6). In more detail, the surface density of Sc on the charge trap layer 4 may be about 10¹⁴ atoms/cm² or greater. When the surface density of Sc doped on the silicon nitride of the charge trap layer is about 10¹⁴ atoms/cm² or greater, the charge trap layer 4 may have excellent (e.g., increased, improved, etc.) charge retention property. When the surface density of Sc doped on the silicon nitride is 10¹⁴ atoms/cm² or greater, the charge trap layer 4 may have high processing reliability. As a result, a vertical structure memory device, and any device including same (e.g., a memory device, electronic apparatus, or the like) may have improved data storage capabilities, including improved charge retention, stored data retention, improved read window, or the like, and thus may have improved data storage functionality and improved data storage reliability, based on the vertical structure memory device including a charge trap layer that includes a nitride doped with scandium wherein the surface density of the dopant (e.g., doped Sc) on the charge trap layer 3 (e.g., an outer surface thereof) is equal to or greater than about 10¹⁴ atoms/cm². However, the above description about the surface density of Sc is an example, and example embodiments are not limited to the above examples.

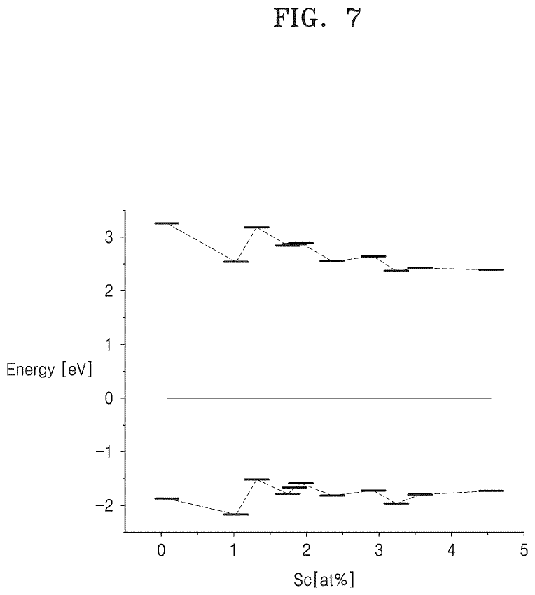

FIG. 7 is a graph showing an energy band of the charge trap layer 4 according to a content of Sc doped on the charge trap layer 4 according to some example embodiments, where such charge trap layer 4 may be the charge trap layer 4 of the vertical structure memory device 1 shown in FIG. 1-4, although example embodiments are not limited thereto. FIG. 7 is a graph showing an energy band of the charge trap layer 4 measured while doping the silicon nitride with Sc.

Referring to FIGS. 5 to 7, the charge trap layer 4 including silicon nitride doped with Sc may have an energy band that may be close to the energy band of silicon. The charge trap layer 4 including silicon nitride doped with Sc may maintain a band gap of 1 eV or greater while reducing the band gap. The charge trap layer 4 including silicon nitride doped with Sc may facilitate a programming (PGM) operation of the memory cells MC. The charge trap layer 4 including silicon nitride doped with Sc may facilitate an erase (ERS) operation of the memory cells MC.

Referring back to FIGS. 2 to 7, the vertical structure memory device 1 according to some example embodiments may include the charge trap layer 4 doped with Sc. The charge trap layer 4 may include the nitride 40 doped with Sc. The content, in the charge trap layer 4, of Sc doped on the charge trap layer 4 may be about 2 at % to about 10 at %. The content, in the charge trap layer 4, of Sc doped on the charge trap layer 4 may be about 2.7 at % to about 5 at %. The surface density of Sc doped on the charge trap layer 4 (e.g., an outer surface thereof) may be about 10¹⁴ atoms/cm² or greater. However, the content of Sc is an example, and some example embodiments are not limited thereto.

In the charge trap layer 4 according to some example embodiments, Sc may be doped on the nitride 40. Sc may be doped on the silicon nitride. Sc may be doped on silicon oxynitride. However, the above description about the nitride 40 on which Sc is doped is an example, and some example embodiments are not limited thereto.

In the charge trap layer according to some example embodiments, Sc may be doped to be evenly distributed in the nitride 40. Sc may be doped while forming a layer-by-layer structure in the nitride 40. However, a method of doping Sc on the nitride 40 is not limited to the above description.

The vertical structure memory device 1 according to some example embodiments may include the charge trap layer 4 having high charge retention property. The vertical structure memory device 1 may include the charge trap layer 4 having high processing reliability. The vertical structure memory device 1 may include the charge trap layer 4 having a charge mobility that is not high in a lateral direction. In other words, in the vertical structure memory device 1, the charges trapped by the charge trap layer 4 corresponding to the gate electrode 3 may not move in the direction toward adjacent gate electrode 3. However, the above description is an example, and some example embodiments are not limited thereto.

Hereinafter, the vertical structure memory device 1 including nano-crystals 50 is described below. Redundant descriptions are omitted, and the differences are described below.

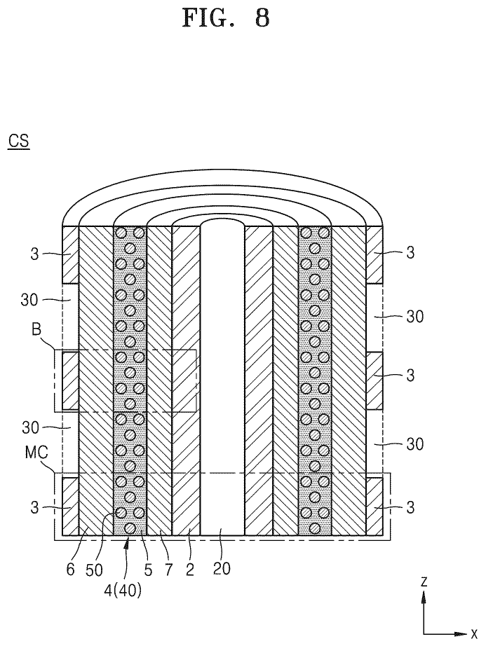

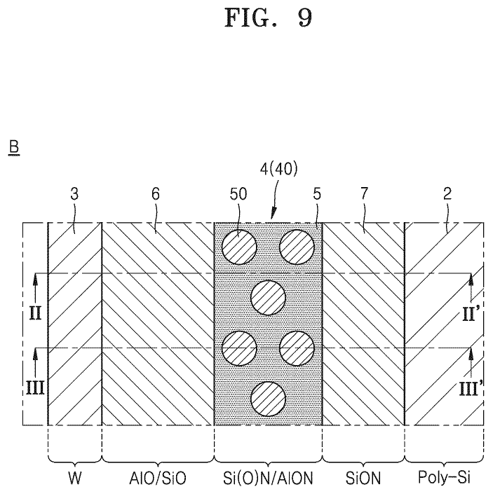

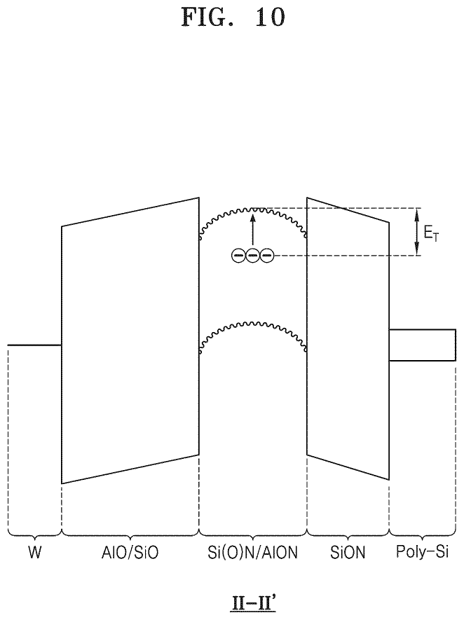

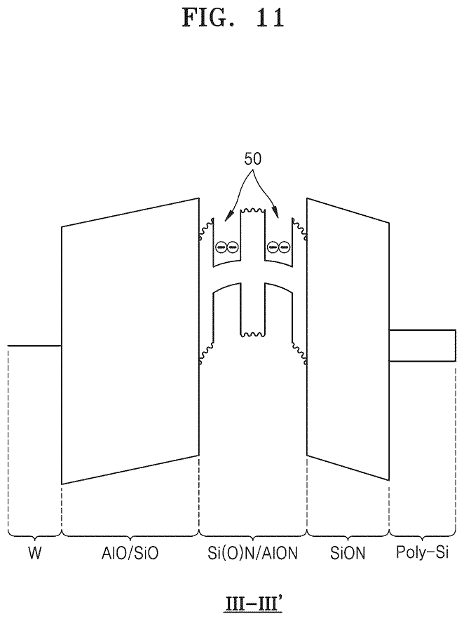

FIG. 8 is a cross-sectional view of a cell string CS according to some example embodiments. FIG. 9 is an enlarged view of part B in the memory cell MC of FIG. 8 according to some example embodiments. FIG. 10 is a diagram schematically showing an electronic band structure taken along line II-II′ of FIG. 9 according to some example embodiments. FIG. 11 is a diagram schematically showing an electronic band structure taken along line III-III′ of FIG. 9 according to some example embodiments.

Referring to FIGS. 1 and 8 to 11, the charge trap layer 4 according to some example embodiments may include a matrix 5 including amorphous nitride 40. The charge trap layer 4 may include nano-crystals 50 that are distributed in the matrix 5 and have semiconductor characteristics. The nitride 40 may include at least one of silicon nitride or silicon oxynitride. The nitride 40 may include aluminum oxynitride. The nano-crystals 50 may be provided to be spatially spaced apart from one another (e.g., spaced apart from each other) in the amorphous matrix 5. The band gap of the nano-crystals 50 may be less (e.g., smaller) than the band gap of the nitride 40 forming the amorphous matrix 5. Additional barriers for the charges trapped in the nano-crystals 50 are formed due to a type-I band alignment structure at the interfaces between the amorphous matrix 5 and the nano-crystals 50, and thus, the electron charge density of the charge trap layer 4 may increase based on including the matrix 5 and nano-crystals 50. As described above, when the charge trap layer 4 is formed of the amorphous nitride 40 in which the nano-crystals 50 having the semiconductor characteristics are dispersed, the trap energy and trap density of the charge trap layer 4 may be increased, and the moving of the trapped charges between the memory cells MC is restrained so as to improve the charge retention property. As a result, a vertical structure memory device, and any device including same (e.g., a memory device, electronic apparatus, or the like) may have improved data storage capabilities, including improved charge retention, stored data retention, improved read window, or the like, and thus may have improved data storage functionality and improved data storage reliability, based on the vertical structure memory device including memory cells MC having a charge trap layer that includes the amorphous nitride 40 in which the nano-crystals 50 having the semiconductor characteristics are dispersed.

The nano-crystals 50 of the charge trap layer 4 according to some example embodiments may include Sc. The nano-crystals 50 may include Sc doped on the nitride 40. The nano-crystals 50 may be at least part of the nitride 40 that is grown by using the Sc as a crystal nucleus. In other words, at least part of the nitride 40 may be grown to the nano-crystals 50 by using the Sc doped on the nitride 40 as the crystal nucleus. However, the method of forming the nano-crystals 50 is an example, and is not limited to the above example. Also, the element doped on the silicon nitride may include another lanthanide element, e.g., lutetium (Lu), other than Sc.

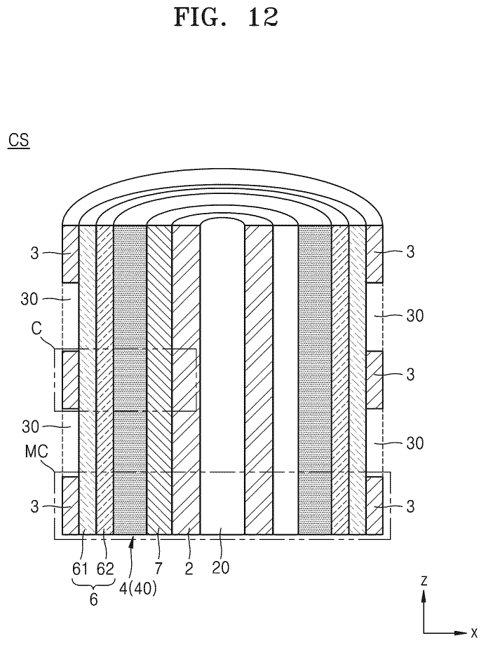

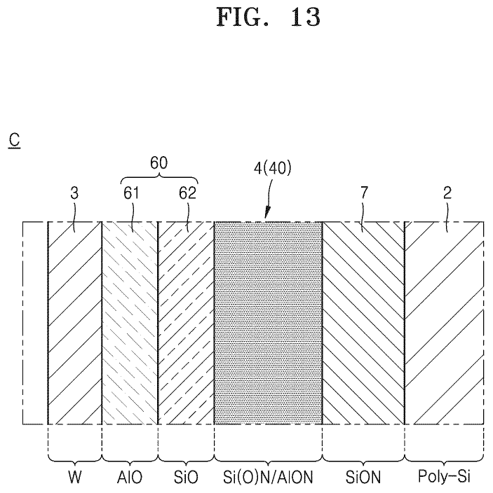

FIG. 12 is a cross-sectional view of a cell string CS according to some example embodiments. FIG. 13 is an enlarged view of part C in the memory cell MC of FIG. 12 according to some example embodiments.

Referring to FIGS. 12 and 13, the insulating layer 6 according to some example embodiments may include a first insulating layer 61 and a second insulating layer 62. The first insulating layer 61 may be disposed between the gate electrode 3 and the charge trap layer 4. The second insulating layer 62 may be disposed between the charge trap layer 4 and the first insulating layer 61. In other words, the first insulating layer 61, the second insulating layer 62, and the charge trap layer 4 may be arranged in the stated order, for example arranged sequentially such that the second insulating layer 62 is between the first insulating layer 61 and the charge trap layer 4.

The first insulating layer 61 according to some example embodiments may include aluminum oxide. The aluminum oxide included in the first insulating layer 61 may be crystallized aluminum oxide. The first insulating layer 61 may block the charges from moving from the gate electrode 3 to the charge trap layer 4. However, the above description about the structure and function of the first insulating layer 61 is an example, and some example embodiments are not limited thereto.

The second insulating layer 62 according to some example embodiments may include silicon oxide. The silicon oxide included in the second insulating layer 62 may be amorphous silicon oxide. The second insulating layer 62 may block the charges trapped by the charge trap layer 4 from moving toward the gate electrode 3. However, the above description about the structure and function of the second insulating layer 62 is an example, and some example embodiments are not limited thereto.

The charge trap layer 4 according to some example embodiments may come into contact (e.g., may be in contact) with the second insulating layer 62. A surface of the charge trap layer 4, the surface being opposite to the surface coming into contact with the tunneling layer 2, may come into contact (e.g., may be in contact) with the second insulating layer 62. However, the arrangement relationship between the charge trap layer 4 and the second insulating layer 62 is not limited to the above description.

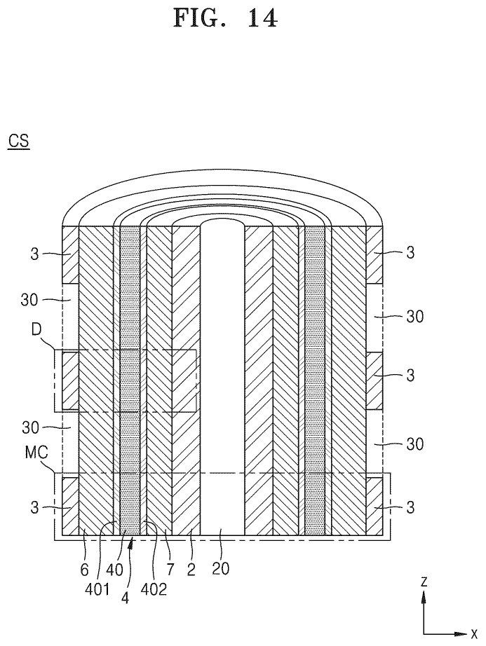

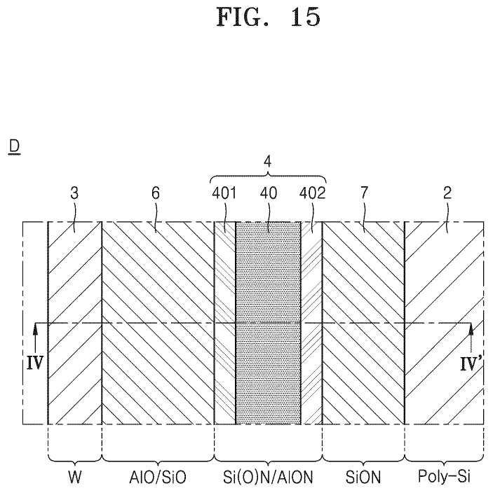

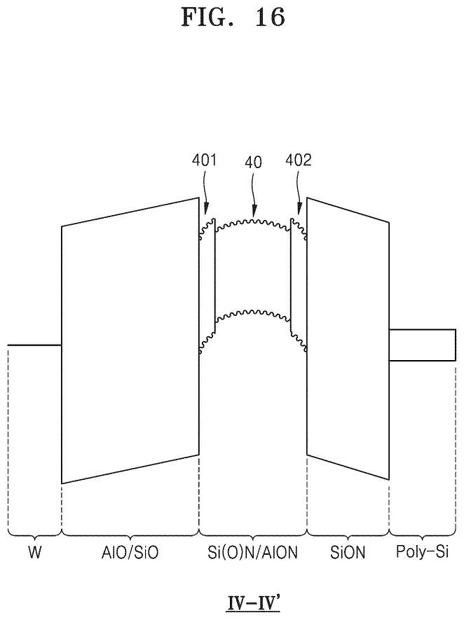

FIG. 14 is a cross-sectional view of a cell string CS according to some example embodiments. FIG. 15 is an enlarged view of part D in the memory cell MC of FIG. 14 according to some example embodiments. FIG. 16 is a diagram schematically showing an electronic band structure taken along line IV-IV′ of FIG. 15 according to some example embodiments.

Referring to FIGS. 14 to 16, the charge trap layer according to some example embodiments may include a first diffusion barrier layer 401 disposed on one surface of the nitride 40. The first diffusion barrier layer 401 may be disposed between the nitride 40 and the insulating layer 6 The first diffusion barrier layer 401 may include silicon nitride or silicon oxynitride. The first diffusion barrier layer 401 may have a thickness, for example, of about 5 nm or less (e.g., about 0.01 nm to about 5 nm, about 0.1 nm to about 5 nm, about 1 nm to about 5 nm, about 2 nm to about 5 nm, etc.). The thickness of the first diffusion barrier layer 401 may be about, for example, 2 nm or less (e.g., about 0.01 nm to about 2 nm, about 0.1 nm to about 2 nm, about 1 nm to about 2 nm, etc.).

The charge trap layer 4 according to some example embodiments may include a second diffusion barrier layer 402. The second diffusion barrier layer 402 may be disposed on the other surface of the nitride 40, which is opposite to the surface where the first diffusion barrier layer 401 is disposed. The second diffusion barrier layer 402 may be disposed between the nitride 40 and the tunneling layer 7. The second diffusion barrier layer 402 may include silicon nitride or silicon oxynitride. The second diffusion barrier layer 402 may have a thickness, for example, of about 5 nm or less (e.g., about 0.01 nm to about 5 nm, about 0.1 nm to about 5 nm, about 1 nm to about 5 nm, about 2 nm to about 5 nm, etc.). The second diffusion barrier layer 402 may have a thickness, for example, of about 2 nm or less (e.g., about 0.01 nm to about 2 nm, about 0.1 nm to about 2 nm, about 1 nm to about 2 nm, etc.).

The first diffusion barrier layer 401 and the second diffusion barrier layer 402 may have different thicknesses from each other, but may have the same thickness as each other. The first diffusion barrier layer 401 and the second diffusion barrier layer 402 may have (e.g., may partially or entirely comprise) the same material, but may have different materials (e.g., may have different total material compositions).

The first diffusion barrier layer 401 and the second diffusion barrier layer 402 according to some example embodiments may prevent Sc doped on the nitride 40 from being diffused to the outer side of the charge trap layer 4, or may reduce or minimize such diffusion. In more detail, the first diffusion barrier layer 401 may prevent the Sc doped on the nitride 40 from being diffused to the insulating layer 6, or may reduce or minimize such diffusion. The second diffusion barrier layer 402 may prevent Sc doped on the nitride 40 from being diffused to the tunneling layer 7, or may reduce or minimize such diffusion.

Because the charge trap layer 4 according to some example embodiments may include the first diffusion barrier layer 401 and/or the second diffusion barrier layer 402, the degradation in device characteristics due to the diffusion of Sc doped on the nitride 40 may be reduced, minimized, or prevented, thereby improving the functionality of memory cells, MC, a cell string SC, a vertical structure memory device 1, and/or an electronic apparatus including same.

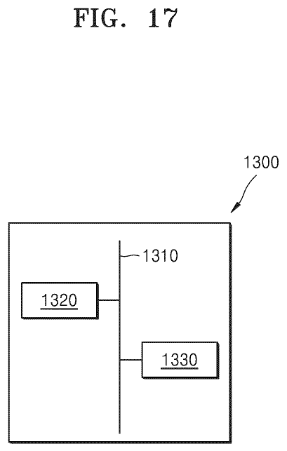

FIG. 17 is a schematic view of an electronic apparatus according to some example embodiments.

Referring to FIG. 17, an electronic apparatus 1300 includes a processor 1320 and a memory 1330 electrically connected through a bus 1310. In some example embodiments, the electronic apparatus 1300 may include one or more additional devices, including for example a sensor, a display device, a user interface, or any combination thereof. The sensor may include, for example, an image sensor, a camera device, a CMOS image sensor, a photoelectric conversion device, any combination thereof, or the like. The display device may include, for example a light emitting diode (LED) display panel, an organic LED (OLED) display panel, or the like. The user interface may include a set of one or more buttons, a keyboard, a touchscreen display (which may be included with the aforementioned display device), or any combination thereof. The processor 1320 may perform a memory program which may be stored at the memory 1330 and thus at least one function. The processor 1320 may generate an output. The memory 1330 may include at least one vertical structure memory device 1 according to any of the example embodiments.

The processor 1320 may include processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processor 1320 may be configured to generate an output (e.g., an image to be displayed on a display interface) based on such processing. One or more of the processor 1320 or the memory 1330 may be included in, include, and/or implement one or more instances of processing circuitry such as hardware including logic circuits, a hardware/software combination such as a processor executing software; or any combination thereof. In some example embodiments, said one or more instances of processing circuitry may include, but are not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, any of the memories, memory units, or the like as described herein may include a non-transitory computer readable storage device, for example a solid state drive (SSD), storing a program of instructions, and the one or more instances of processing circuitry may be configured to execute the program of instructions to implement the functionality of some or all of any of the electronic apparatus 1300, processor 1320, memory 1330, or the like according to any of the example embodiments as described herein. In some example embodiments, the memory 1330 may have improved reliability and/or lifespan, and thus the electronic apparatus 1300 may have improved reliability and/or lifespan and thus improved functionality, based on the memory 1330 including at least one vertical structure memory device 1 according to any of the example embodiments, where the vertical structure memory device includes at least one channel string that includes a channel layer extending in a direction perpendicular to a substrate, a charge trap layer on the channel layer, the charge trap layer including a nitride doped with scandium (Sc), and a plurality of gate electrodes on the charge trap layer, wherein, in the charge trap layer, a content of doped Sc is 2 atomic percent (at %) to 10 at %.

The vertical structure memory device according to some example embodiments may provide the charge trap layer including the nitride having high dielectric constant.

The vertical structure memory device according to some example embodiments may provide the charge trap layer including the nitride having high electron trap density.

The vertical structure memory device according to some example embodiments may provide the charge trap layer having high charge retention property.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A vertical structure memory device, comprising:
a cell string, the cell string including
a channel layer extending in a direction perpendicular to a substrate,
a charge trap layer on the channel layer, the charge trap layer including a nitride doped with scandium (Sc), and
a plurality of gate electrodes on the charge trap layer,
wherein a content of doped Sc in the charge trap layer is 2 atomic percent (at %) to 10 at % as a proportion of a total composition of the charge trap layer.

2. The vertical structure memory device of claim 1, wherein the nitride includes at least one of silicon nitride or silicon oxynitride.

3. The vertical structure memory device of claim 1, wherein the nitride includes aluminum oxynitride.

4. The vertical structure memory device of claim 2, wherein the content of doped Sc in the charge trap layer is 2.7 at % to 5 at %.

5. The vertical structure memory device of claim 2, wherein a surface density of the doped Sc in the charge trap layer is equal to or greater than 10¹⁴ atoms/cm².

6. The vertical structure memory device of claim 1, wherein the charge trap layer comprises
an amorphous matrix, the amorphous matrix including the nitride, and
nano-crystals distributed in the amorphous matrix, the nano-crystals having semiconductor characteristics.

7. The vertical structure memory device of claim 6, wherein the nano-crystals include the doped Sc thereon.

8. The vertical structure memory device of claim 7, wherein the nano-crystals include the nitride grown based on using the doped Sc as a crystal nucleus.

9. The vertical structure memory device of claim 8, wherein the nitride includes at least one of silicon nitride or silicon oxynitride.

10. The vertical structure memory device of claim 8, wherein the nitride includes aluminum oxynitride.

11. The vertical structure memory device of claim 1, further comprising:
a first insulating layer between each separate gate electrode of the plurality of gate electrodes and the charge trap layer, the first insulating layer including aluminum oxide; and
a second insulating layer between the charge trap layer and the first insulating layer, the second insulating layer including silicon oxide.

12. The vertical structure memory device of claim 11, wherein the first insulating layer, the second insulating layer, and the charge trap layer are sequentially arranged such that the second insulating layer is between the first insulating layer and the charge trap layer.

13. The vertical structure memory device of claim 12, further comprising:
a tunneling layer between the channel layer and the charge trap layer,
wherein one surface of the charge trap layer is in contact with the tunneling layer and an opposite surface of the charge trap layer is in contact with the second insulating layer.

14. The vertical structure memory device of claim 1, wherein the charge trap layer comprises a first diffusion barrier layer on one surface of the nitride.

15. The vertical structure memory device of claim 14, wherein the charge trap layer comprises a second diffusion barrier layer on another surface of the nitride, the other surface of the nitride being opposite to the one surface of the nitride.

16. The vertical structure memory device of claim 15, wherein the first diffusion barrier layer and the second diffusion barrier layer each independently include silicon nitride or silicon oxynitride.

17. The vertical structure memory device of claim 1, wherein the charge trap layer has a cylindrical shape surrounding the channel layer.

18. The vertical structure memory device of claim 17, wherein the plurality of gate electrodes are spaced apart from each other in the direction perpendicular to the substrate.

19. The vertical structure memory device of claim 18, wherein each gate electrode of the plurality of gate electrodes surrounds the charge trap layer.

20. An electronic apparatus comprising the vertical structure memory device according to claim 1.
